(19) United States
(12) Patent Application Publication
(10) Pub. No.: US 2022/0254825 A1
(43) Pub. Date: Aug. 11, 2022

(54) THERMAL SENSOR MODULE WITH DUAL PACKAGE

(71) Applicant: Spring Rainbow Optics Co., LTD, Taoyuan City (TW)

(72) Inventors: SHIH-HAN CHEN, New Taipei City (TW); PO-LIANG CHIANG, Taipei City (TW)

(21) Appl. No.: 17/667,563

(22) Filed: Feb. 9, 2022

Related U.S. Application Data
(60) Provisional application No. 63/147,256, filed on Feb. 9, 2021.

(51) Int. Cl. H01L 27/146

(52) U.S. Cl. CPC H01L 27/14618; H01L 27/14683; H01L 27/14627; H01L 27/14649

(57) ABSTRACT

A thermal sensor module is disclosed and includes a substrate; a thermal sensor disposed on the substrate; an inner package structure disposed on the substrate, surrounding the thermal sensor, and encapsulating the thermal sensor together with the substrate; wherein the inner package structure includes an inner top window; an outer package structure disposed on the substrate, surrounding the inner package structure, and packaging the thermal sensor together with the substrate; wherein the outer package structure includes an outer top window; wherein an orthographic projection of the inner top window projected on the substrate at least partially covers the thermal sensor, and an orthographic projection of the outer top window projected on the substrate at least partially covers the orthographic projection of the inner top window projected on this substrate.

### CROSS REFERENCE TO RELATED APPLICATIONS

The present application claims the benefit of priority under 35 USC 119(e) of U.S. Provisional Patent Application No. 63/147,256 entitled “THERMAL SENSOR MODULE WITH DUAL PACKAGE” and filed on Feb. 9, 2021, the contents of which are incorporated herein by reference in their entirety.

### FIELD OF INVENTION

The present disclosure relates to the technical field of a thermal sensor, and particularly to a thermal sensor module with dual packages.

### BACKGROUND OF DISCLOSURE

Sensors used for sensing temperature (or referred to as sensing far-infrared images, and in this disclosure, specifically referred to as sensing far-infrared rays with wavelengths ranging from 2.5 μm to 20 μm) are often packaged in a vacuum condition or in an environment filled with nitrogen gas. It is known that heat is transmitted through radiation, convection, and conduction. Radiation is the signal that should be detected by the far-infrared sensors. If there is general air close to the sensor, the ambient temperature easily achieves the sensor by convection and becomes noise background.

As shown in FIG. 1, common packages of the thermal sensors 3 has the following problems:

(1) An ultra-high vacuum (usually below 200 m torr) is required to reduce thermal noise from air convection. Therefore, during manufacturing processes, it is necessary to exhaust air for a long time to achieve an ultra-high vacuum, or fill with nitrogen, to reduce thermal noise by nitrogen gas, which has low thermal conductivity.

(2) Since the interior of the package structure 5 is close to a perfect vacuum, there is a huge pressure difference from the pressure of the outer environment (usually about 1 atmosphere; about 760 torr). In order to avoid deformation of the overall package structure 5 caused by such a huge pressure difference, and maintain long-term vacuum stability to avoid air leakage, the package structure 5, top window 6, and sealant 7 must be made of highly rigid and relatively expensive materials (the package structure 5 is typically made of metal, the top window 6 is typically made of silicon or germanium, and the sealant 7 should be heated under high temperature for a long time to ensure its hardness, rigidity and durability after cured).

By this traditional method, it also has difficulty in directly packaging an optical lens with curvature or an aspheric coefficient in the thermal sensor module 2, because the huge pressure difference between interior and exterior easily causes the lens to deform and lose its original optical function, and the package structure 5 may also slightly deform and cause the lens to shift. Therefore, it is only suitable for packaging flat windows without focusing function.

### SUMMARY OF INVENTION

A primary object of the present disclosure is to provide a thermal sensor module, preventing an overall package structure from deformation and air leakage caused by huge pressure difference, and being able to easily mount a lens with curvature.

To achieve the above object, an aspect of the present disclosure provides a thermal sensor module including:

a substrate;

a thermal sensor disposed on the substrate;

an inner package structure disposed on the substrate, surrounding the thermal sensor, and packaging the thermal sensor together with the substrate; wherein the inner package structure includes an inner top window allowing transmission of thermal radiation; and

an outer package structure disposed on the substrate, surrounding the inner package structure, and packaging the thermal sensor together with the substrate; wherein the outer package structure includes an outer top window allowing transmission of thermal radiation;

wherein an orthographic projection of the inner top window projected on the substrate at least partially covers the thermal sensor, and an orthographic projection of the outer top window projected on the substrate at least partially covers the orthographic projection of the inner top window projected on this substrate.

In accordance with an embodiment of the present disclosure, there is an inner space within the inner package structure, there is an outer space between the inner package structure and the outer package structure; wherein atmospheric pressures of the inner space and the outer space range from 200 mtorr to 50000 mtorr.

In accordance with an embodiment of the present disclosure, a connection structure is configured between the inner package structure and the outer package structure to connect the inner packaging structure with the outer packaging structure, and the inner package structure, the outer package structure and the connection structure are integrally formed in one piece.

In accordance with an embodiment of the present disclosure, the connection structure extends from an inner package sidewall of the inner package structure to an outer package top wall of the outer package structure and a periphery of the outer top window along a direction of the inner package sidewall for supporting the outer package top wall and the periphery of the outer top window.

In accordance with an embodiment of the present disclosure, the connection structure extends from an inner package top wall of the inner package structure to an outer package sidewall of the outer package structure along a direction of the inner package top wall for supporting the outer package sidewall.

In accordance with an embodiment of the present disclosure, the outer top window and the inner top window are lenses with curvatures and cooperate as an imaging system to focus radiant energy on the thermal sensor.

In accordance with an embodiment of the present disclosure, material of the outer top window and the inner top window includes a plastic and an additive, and the additive is selected from the group consisting of germanium, silicon, potassium bromide, sodium chloride, zinc sulfide, zinc selenide and combinations thereof

In accordance with an embodiment of the present disclosure, material of the inner package structure and the outer package structure is selected from polycarbonate (PC), polymethyl methacrylate (PMMA), polyethylene (PE), high density polyethylene (HDPE), polypropylene (PP), polystyrene (PS), polyethylene terephthalate (PET), nylon, thermosetting plastics, phenolic resin, melamine-formaldehyde resin, epoxy resin, unsaturated polyester, silicone, and combinations thereof.

To achieve the above object, an aspect of the present disclosure provides a thermal sensor module including:

a substrate;

a thermal sensor disposed on the substrate;

an inner package structure disposed on the substrate and including an inner package sidewall and an inner top window, wherein the inner top window allows transmission of thermal radiation, the inner package sidewall surrounds the thermal sensor, the inner top window is located over the thermal sensor, and the inner package structure and the substrate jointly package the thermal sensor; and

an outer package structure disposed on the substrate and including an outer package sidewall and an outer top window, wherein the outer top window allows transmission of thermal radiation, the outer package sidewall surrounds the inner package sidewall, the outer top window is located over the inner top window, and the outer package structure and the substrate jointly package the thermal sensor;

wherein an orthographic projection of the inner top window projected on the substrate at least partially covers the thermal sensor, and an orthographic projection of the outer top window projected on the substrate at least partially covers the orthographic projection of the inner top window projected on this substrate.

In accordance with an embodiment of the present disclosure, there is an inner space within the inner package structure, there is an outer space between the inner package structure and the outer package structure; wherein atmospheric pressures of the inner space and the outer space range from 200 mtorr to 50000 mtorr.

In accordance with an embodiment of the present disclosure, a connection structure is configured between the inner package structure and the outer package structure to connect the inner packaging structure with the outer packaging structure, and the inner package structure, the outer package structure and the connection structure are integrally formed in one piece.

In accordance with an embodiment of the present disclosure, the connection structure extends from the inner package sidewall of the inner package structure to an outer package top wall of the outer package structure and a periphery of the outer top window along a direction of the inner package sidewall for supporting the outer package top wall and the periphery of the outer top window.

In accordance with an embodiment of the present disclosure, the connection structure extends from an inner package top wall of the inner package structure to the outer package sidewall of the outer package structure along a direction of the inner package top wall for supporting the outer package sidewall.

In accordance with an embodiment of the present disclosure, the outer top window and the inner top window are lenses with curvatures and cooperate as an imaging system to focus radiant energy on the thermal sensor.

In accordance with an embodiment of the present disclosure, material of the outer top window and the inner top window includes a plastic and an additive, and the additive is selected from the group consisting of germanium, silicon, potassium bromide, sodium chloride, zinc sulfide, zinc selenide and combinations thereof.

In accordance with an embodiment of the present disclosure, material of the inner package structure and the outer package structure is selected from polycarbonate (PC), polymethyl methacrylate (PMMA), polyethylene (PE), high density polyethylene (HDPE), polypropylene (PP), polystyrene (PS), polyethylene terephthalate (PET), nylon, thermosetting plastics, phenolic resin, melamine-formaldehyde resin, epoxy resin, unsaturated polyester, silicone, and combinations thereof.

To achieve the above object, an aspect of the present disclosure provides a method of packaging a thermal sensor module including:

Step S10: providing a package structure, an inner top window, an outer top window, a substrate, and a thermal sensor, wherein the substrate carries the thermal sensor;

Step S20: combining the package structure with the inner top window, wherein the package structure includes an inner package structure and an outer package structure, and fixedly mounting the inner top window into an inner opening defined by a top wall of the inner package structure;

Step S30: placing the package structure, the outer top window, and the substrate in a chamber, and placing the package structure on the substrate to completely cover the thermal sensor;

Step S40: exhausting air from the chamber, so that an inner space in the inner packaging structure and an outer space between the inner package structure and the outer package structure are all under a same atmospheric pressure;

Step S50: combining the package structure with the outer top window, and fixedly mounting the outer top window into an outer opening defined by a top wall of the outer package structure; and

Step S60: taking out the package structure from the chamber to obtain the packaged thermal sensor module.

In accordance with an embodiment of the present disclosure, in Step S20 of combining the package structure with the inner top window, the inner top window is fixedly mounted onto the inner package structure by gluing and curing; and in Step S50 of combining the package structure with the outer top window, the outer top window is fixedly mounted onto the outer package structure by gluing and curing.

In accordance with an embodiment of the present disclosure, after Step S40 of exhausting air from the chamber, the method further includes a step of fixedly mounting the package structure onto the substrate by gluing and curing.

In accordance with an embodiment of the present disclosure, in Step S40 of exhausting air from the chamber, the atmospheric pressure in the chamber ranges from 200 mtorr to 50000 mtorr.

In summary, in accordance with an embodiment of the present disclosure, the thermal sensor module has a dual-layer structure, i.e. the inner package structure 30 and the outer package structure, thereby including two layers of vacuums, which are respectively in the inner space and in the outer space. The inner package structure and the outer package structure have low thermal conductivity, so as to reduce the noise effect generated by thermal convection on the thermal sensor. Moreover, because the pressure in the inner space is close to that in the outer space, the inner top window and the inner package structure are not subjected to a huge pressure difference and are not easily deformed and displaced. Therefore, it is easy to use an optical lens with curvature as the inner top window of the inner package structure. In addition, in one embodiment, the area of the outer top window is configured to be relatively small, and the connection structure supports the outer top window to enhance durability, sturdiness, and longevity of the packaged thermal sensor module.

### BRIEF DESCRIPTION OF DRAWINGS

With reference to the following detailed description and in conjunction with the accompanying drawings, the foregoing aspects of the present disclosure and many accompanying advantages may be easily understood, wherein:

FIG. 1 is a cross-sectional side view showing a conventional thermal sensor module.

FIG. 2 is a cross-sectional side view showing a thermal sensor module in accordance with an embodiment of the present disclosure.

FIG. 3A and FIG. 3B are cross-sectional side views respectively showing thermal sensor modules in accordance with a first embodiment and a second embodiment of the present disclosure.

FIG. 4A and FIG. 4B are perspective views respectively showing the thermal sensor modules in accordance with the first embodiment and the second embodiment of the present disclosure.

FIG. 5 is a flowchart showing steps of a method for packaging a thermal sensor module in accordance with an embodiment of the present disclosure.

FIG. 6 is a schematic perspective view showing step S20 in the method for packaging the thermal sensor module in accordance with the embodiment of the present disclosure.

FIG. 7 is a schematic perspective view showing step S30 in the method for packaging the thermal sensor module in accordance with the embodiment of the present disclosure.

FIG. 8 is a schematic perspective view showing step S50 in the method of packaging the thermal sensor module in accordance with the embodiment of the present disclosure.

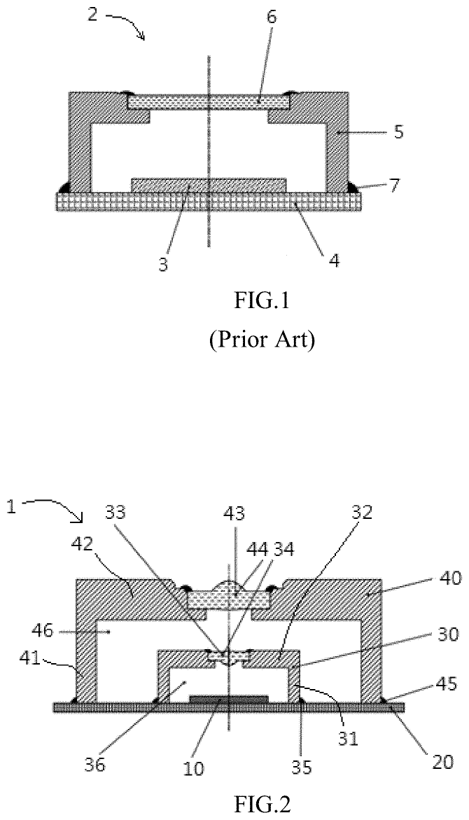

### DETAILED DESCRIPTION OF PREFERRED EMBODIMENTS

The following description of the embodiments with reference to the accompanying drawings is used to illustrate particular embodiments of the present disclosure. The directional terms used in the present disclosure, such as “upper”, “lower”, “front”, “back”, “left”, “right”, “inner”, “outer”, “side surface”, etc., are only directions with regard to the accompanying drawings. Therefore, the directional terms used for describing and illustrating the present disclosure are not intended to limit the present disclosure.

In the drawings, units with similar structures are indicated by the same reference number.

As to an “embodiment” mentioned herein, the particular features, structures, or characteristics described in this embodiment, which may be described in combination with the embodiment, may be included in at least one embodiment of the present disclosure. The phrases appearing at various locations in the specification do not necessarily refer to the same embodiments, nor to the embodiments being alternative to, mutually exclusive with, or independent from other embodiments. It is explicitly and implicitly understood by a person of ordinary skill in the art that the embodiments described herein may be combined with other embodiments.

The content of the present disclosure is described in detail by reference to embodiments below in conjunction with the accompanying drawings.

By reference to the accompanying drawings, the technological content and embodiments of the present disclosure are described in detail as follows:

Refer to FIG. 2, which is a cross-sectional side view showing a thermal sensor module in accordance with an embodiment of the present disclosure. In accordance with an aspect of the present disclosure, the thermal sensor module 1 includes a thermal sensor 10, a substrate 20, an inner package structure 30, and an outer package structure 40.

The thermal sensor 10, the inner package structure 30 and the outer package structure 40 are all disposed on the same side of the substrate 20, and the inner package structure 30 is fixed onto the substrate 20 by an inner sealant 35, the outer package structure 40 is fixed onto the substrate 20 by an outer sealant 45. Preferably, the substrate 20 has a low thermal conductivity.

The inner package structure 30 includes an inner package sidewall 31 and an inner top window 33, wherein the inner top window 33 allows transmission of thermal radiation, the inner package sidewall 31 surrounds the thermal sensor 10, the inner top window 33 is located over the thermal sensor 10, and the inner package structure 30 and the substrate 20 jointly package the thermal sensor 10. Optionally, the inner package structure 30 further includes an inner package top wall 32, the inner top window 33 is disposed in the inner package top wall 32, and the inner package top wall 32 and the inner top window 33 are located over the thermal sensor 10. Specifically, the inner package top wall 32 defines an inner hole 34, where the inner top window 33 is disposed.

The outer package structure 40 includes an outer package sidewall 41 and an outer top window 43, wherein the outer top window 43 transmission of thermal radiation, the outer package sidewall 41 surrounds the inner package sidewall 31, the outer top window 43 is located over the inner top window 33, and the outer packaging structure 40 and the substrate 20 jointly package the thermal sensor 10. Optionally, the outer package structure 40 further includes an outer package top wall 42, the outer top window 43 is disposed in the outer package top wall 42, and the outer package top wall 42 and the outer top window 43 are located over the thermal sensor 10. Specifically, the outer package top wall 42 defines an outer hole 44 where the outer top window 43 is disposed.

In the present disclosure, material of the inner package structure 30 and the outer package structure 40 may be material with thermal conductivity less than 30 W/mK, including but not limited to metal, glass, ceramics, and plastics, and its surface may be coated or painted to reduce its thermal conductivity. In an embodiment, material of the inner package structure and the outer package structure is selected from polycarbonate (PC), polymethyl methacrylate (PMMA), polyethylene (PE), high density polyethylene (HDPE), polypropylene (PP), polystyrene (PS), polyethylene terephthalate (PET), nylon, thermosetting plastics, phenolic resin, melamine-formaldehyde resin, epoxy resin, unsaturated polyester, silicone, and combinations thereof.

An orthographic projection of the inner top window 33 projected on the substrate 20 at least partially covers the thermal sensor 10, and an orthographic projection of the outer top window 43 projected on the substrate 20 at least partially covers the orthographic projection of the inner top window 33 projected on the substrate 20. Preferably, an area of the orthographic projection of the outer top window 43 projected on the substrate 20 is greater than or equal to and completely covers an area of the orthographic projection of the inner top window 33 projected on the substrate 20, Furthermore, the centers of the thermal sensor 10, the inner top window 33, and the outer top window 43 are located on the same axis. More preferably, an area of the orthographic projection of the outer top window 43 projected on the substrate 20 is smaller than or equal to an area of the orthographic projection of the inner package top wall 32 projected on the substrate 20.

There is an inner space 36 within the inner package structure 30, and there is an outer space between the inner package structure and the outer package structure. The inner space 36 and the outer space 46 are exhausted to a near-vacuum atmospheric pressure, preferably ranging from 200 mtorr to 50000 mtorr.

The thermal sensor module 1 has a dual-layer structure, i.e. the inner package structure 30 and the outer package structure 40, thereby including two layers of vacuums, which are respectively in the inner space 36 and in the outer space 46. The inner package structure 30 and the outer package structure 40 have low thermal conductivity, so as to reduce the noise effect generated by thermal convection on the thermal sensor 10. Moreover, because the pressure in the inner space 36 is close to that in the outer space 46, the inner top window 33 and the inner package structure 30 are not subjected to a huge pressure difference and are not easily deformed and displaced. Therefore, it is easy to use an optical lens with curvature as the inner top window 33 of the inner package structure 30.

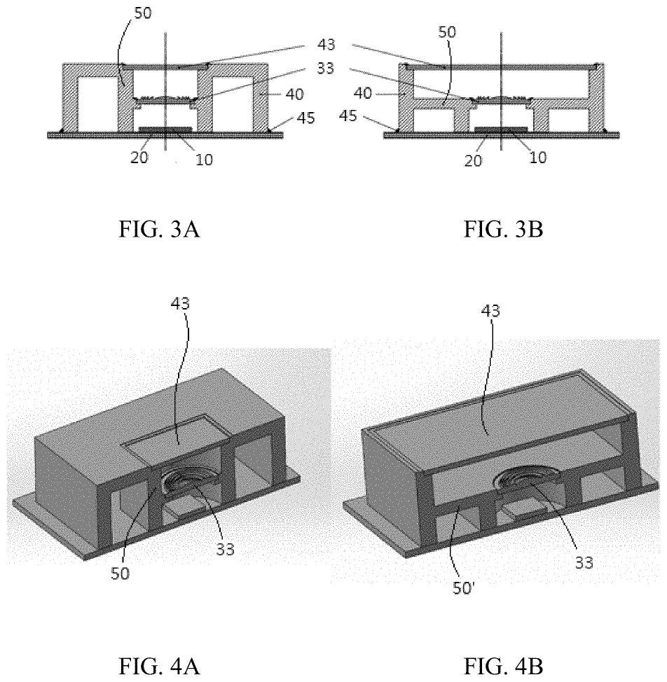

The outer top window 43 and the inner top window 33 allow thermal radiation from the external environment to transmit therethrough. The outer top window 43 may be in the form of a flat plate or a lens with curvature, may have an aspherical coefficient, and may be presented in the form of a Fresnel lens (not shown); the inner top window 33 may be in the form of a flat plate or a lens with curvature, may have an aspherical coefficient, and may be presented in the form of a Fresnel lens (as shown in FIG. 3 to FIG. 7, the inner top window 33 in the form of a Fresnel lens, and the outer top window 43 in the form of a flat plate). In one embodiment, one of the outer top window 43 and the inner top window 33 is a lens with curvature. In another embodiment, both the outer top window 43 and the inner top window 33 are lenses with curvature, which cooperate as an imaging system to focus radiant energy on the thermal sensor, or cooperate with an additional lens as an imaging system to focus radiant energy on the thermal sensor. If both the outer top window 43 and the inner top window 33 have curvatures, they may cooperate (or with the additional lens) as an imaging system for wavelengths ranging from 2.5 μm to 20 μm.

Material of the outer top window 43 and the inner top window 33 may be material capable of transmitting far infrared radiation with wavelengths ranging from 2.5 μm to 20 μm, including but not limited to germanium, silicon, plastic materials, such as polycarbonate (PC), polymethyl methacrylate (PMMA), polyethylene (PE), high density polyethylene (HDPE), polypropylene (PP), polystyrene (PS), polyethylene terephthalate (PET), etc. If the material of the outer top window 43 and the inner top window 33 is made of plastic, an additive may be further included in the material, and the additive may be selected from the group consisting of germanium, silicon, potassium bromide, sodium chloride, zinc sulfide, zinc selenide, and combinations thereof, for improving transmission rates of far infrared radiation.

Refer to FIG. 3A and FIG. 3B, which are cross-sectional side views, and FIG. 4A and FIG. 4B, which are perspective views. FIG. 3A and FIG. 4A show thermal sensor modules in accordance with a first embodiment. FIG. 3B and FIG. 4B show thermal sensor modules in accordance with a second embodiment.

In the first and second embodiments, the thermal sensor module 1 further includes a connection structure 50 configured between the inner package structure 30 and the outer package structure 40 to connect the inner package structure 30 with the outer package structure 40. In an embodiment, the inner package structure 30, the outer package structure 40, and the connection structure 50 are integrally formed into a single piece. When a single-piece integrally formed plastic package structure is employed, the package structure can be formed by a single piece of mold, so as to reduce the costs of materials and molds.

Referring to FIG. 3A and FIG. 4A, in the first embodiment, the connection structure 50 extends from the inner package sidewall 31 of the inner package structure 30 along a direction of the inner package sidewall 31 to the outer package top wall 42 of the outer package structure 40 and a periphery of the outer top window 43 for supporting the outer top wall 42 and the periphery of the outer top window 43. Referring to FIG. 3B and FIG. 4B, in the second embodiment, the connection structure 50′ extends from the inner package top wall 32 of the inner package structure 30 along a direction of the inner package top wall 32 to the outer package sidewall 41 of the outer package structure 40 for supporting the outer package sidewall 41. Compared with the second embodiment, the outer top window 43 in the first embodiment has a smaller area and bears less total pressure, and the connection structure 50 directly supports the outer package top wall 42 and the periphery of the outer top window 43. Although the connection structure 50′ can also support the outer package sidewall 41 in the second embodiment, the outer top window 43 is the element most likely to be broken, since the outer top window 43 is the element directly contacting the external environment, and may be the thinnest element for facilitating transmission of infrared radiation. Configuring the area of the outer top window 43 to be relatively small and supporting the outer top window 43 with the connection structure 50 in the first embodiment can enhance durability, sturdiness, and longevity of the packaged thermal sensor module 1.

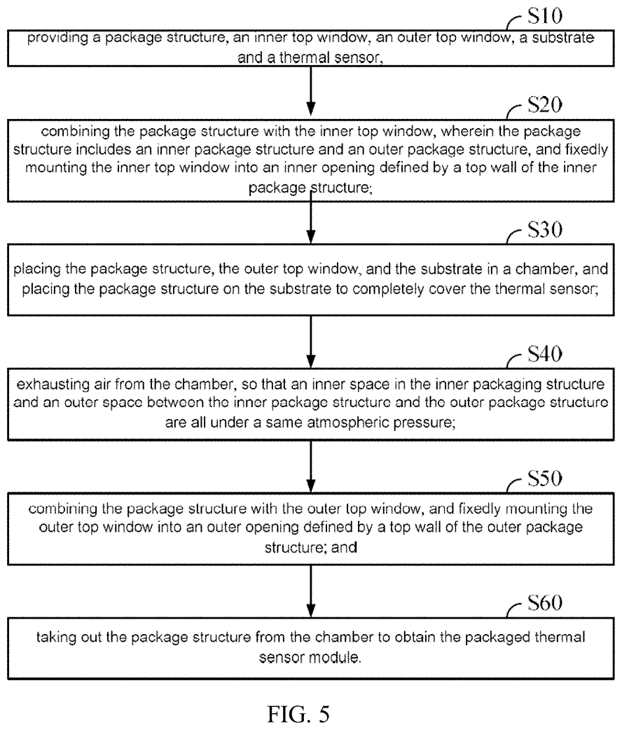

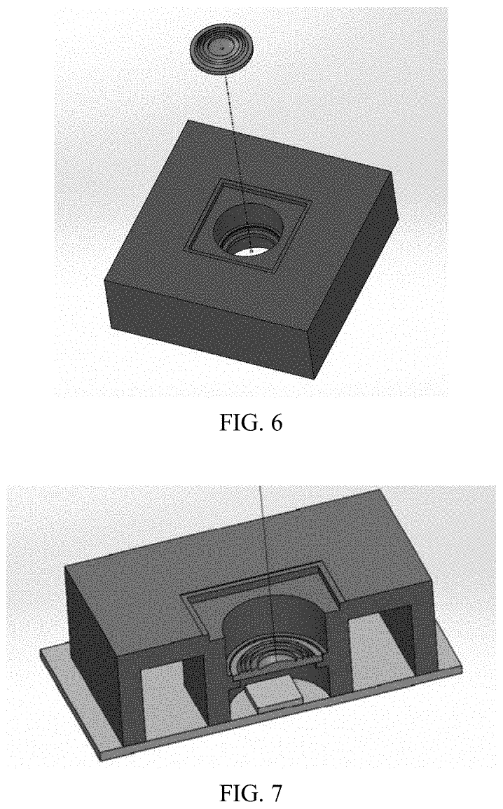

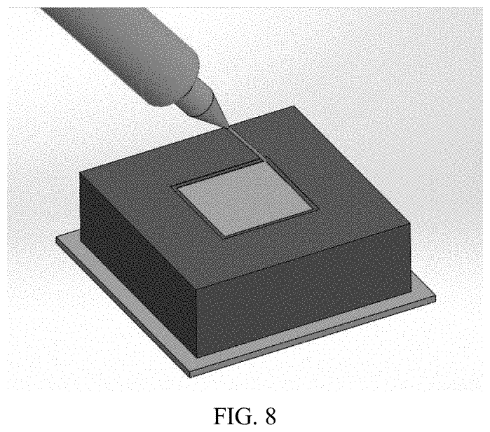

Refer to FIG. 5, which is a flowchart showing steps of a method for packaging a thermal sensor module in accordance with an embodiment of the present disclosure, FIG. 6, which is a schematic perspective view showing step S20 in the method for packaging the thermal sensor module in accordance with an embodiment of the present disclosure, FIG. 7, which is a schematic perspective view showing step S30 in the method for packaging the thermal sensor module in accordance with an embodiment of the present disclosure, and FIG. 8, which is a schematic perspective view showing step S50 in the method of packaging the thermal sensor module in accordance with an embodiment of the present disclosure.

The method for packaging a thermal sensor module includes the following steps:

Step S10: providing a package structure, an inner top window, an outer top window, a substrate, and a thermal sensor, wherein the substrate carries the thermal sensor.

Step S20: combining the package structure with the inner top window, wherein the package structure includes an inner package structure and an outer package structure, and fixedly mounting the inner top window into an inner opening defined by a top wall of the inner package structure, as shown in FIG. 6. In an embodiment, the inner top window is fixedly mounted onto the inner package structure by gluing and curing via ultraviolet light or heating.

Step S30: placing the package structure (which has been combined with the inner top window), the outer top window, and the substrate in a chamber, and placing the package structure on the substrate to completely cover the thermal sensor, as shown in FIG. 7. In an embodiment, in the chamber, there are a robotic arm capable of holding the outer top window, and a glue-dispensing equipment capable of performing a subsequent glue-dispensing process.

Step S40: exhausting air from the chamber to a predetermined vacuum degree, so that an inner space within the inner packaging structure and an outer space between the inner package structure and the outer package structure are all under a same atmospheric pressure. In an embodiment, the atmospheric pressure in the chamber ranges from 200 mtorr to 50000 mtorr.

Step S50: combining the package structure with the outer top window, and fixedly mounting the outer top window into an outer opening defined by a top wall of the outer package structure, as shown in FIG. 8. In an embodiment, the outer top window is placed at the outer opening by a robotic arm, and glued by the glue-dispensing equipment and cured by ultraviolet light or heating, so that the outer top window is fixedly mounted onto the outer package structure (e.g., dispensing glue at the junction between the outer top window and the outer package structure), and the package structure is fixedly mounted onto the substrate (e.g., dispensing glue at the junctions of the package structure and the substrate).

Step S60: taking out the package structure from the chamber by disrupting the vacuum in the chamber to obtain the packaged thermal sensor module.

In summary, in accordance with an embodiment of the present disclosure, the thermal sensor module 1 has a dual-layer structure, i.e. the inner package structure 30 and the outer package structure 40, thereby including two layers of vacuums, which are respectively in the inner space 36 and in the outer space 46. The inner package structure 30 and the outer package structure 40 have low thermal conductivity, so as to reduce the noise effect generated by thermal convection on the thermal sensor 10. Moreover, because the pressure in the inner space 36 is close to that in the outer space 46, the inner top window 33 and the inner package structure 30 are not subjected to a huge pressure difference and are not easily deformed and displaced. Therefore, it is easy to use an optical lens with curvature as the inner top window 33 of the inner package structure 30. In addition, in one embodiment, the area of the outer top window 43 is configured to be relatively small, and the connection structure 50 supports the outer top window 43 to enhance durability, sturdiness, and longevity of the packaged thermal sensor module 1.

The present disclosure has been described with a preferred embodiment thereof and it is understood that various modifications, without departing from the spirit of the present disclosure, are in accordance with the embodiments of the present disclosure. Hence, the embodiments described are intended to cover the modifications within the scope and the spirit of the present disclosure, rather than to limit the present disclosure.

In summary, although the preferable embodiments of the present disclosure have been disclosed above, the embodiments are not intended to limit the present disclosure. A person of ordinary skill in the art, without departing from the spirit and scope of the present disclosure, can make various modifications and variations. Therefore, the scope of the disclosure is defined in the claims.

What is claimed is:

1. A thermal sensor module comprising:
a substrate;
a thermal sensor disposed on the substrate;
an inner package structure disposed on the substrate, surrounding the thermal sensor, and packaging the thermal sensor together with the substrate; wherein the inner package structure includes an inner top window allowing transmission of thermal radiation; and
an outer package structure disposed on the substrate, surrounding the inner package structure, and packaging the thermal sensor together with the substrate; wherein the outer package structure includes an outer top window allowing transmission of thermal radiation;
wherein an orthographic projection of the inner top window projected on the substrate at least partially covers the thermal sensor, and an orthographic projection of the outer top window projected on the substrate at least partially covers the orthographic projection of the inner top window projected on this substrate.

2. The thermal sensor module as claimed in claim 1, wherein there is an inner space within the inner package structure, and there is an outer space between the inner package structure and the outer package structure; wherein atmospheric pressures of the inner space and the outer space range from 200 mtorr to 50000 mtorr.

3. The thermal sensor module as claimed in claim 1, wherein a connection structure is configured between the inner package structure and the outer package structure to connect the inner packaging structure with the outer packaging structure, and the inner package structure, the outer package structure and the connection structure are integrally formed in one piece.

4. The thermal sensor module as claimed in claim 3, wherein the connection structure extends from an inner package sidewall of the inner package structure to an outer package top wall of the outer package structure and a periphery of the outer top window along a direction of the inner package sidewall for supporting the outer package top wall and the periphery of the outer top window.

5. The thermal sensor module as claimed in claim 3, wherein the connection structure extends from an inner package top wall of the inner package structure to an outer package sidewall of the outer package structure along a direction of the inner package top wall for supporting the outer package sidewall.

6. The thermal sensor module as claimed claim 1, wherein the outer top window and the inner top window are lenses with curvatures and cooperate as an imaging system to focus radiant energy on the thermal sensor.

7. The thermal sensor module as claimed claim 1, wherein material of the outer top window and the inner top window includes a plastic and an additive, and the additive is selected from the group consisting of germanium, silicon, potassium bromide, sodium chloride, zinc sulfide, zinc selenide and combinations thereof.

8. The thermal sensor module as claimed described in claim 1, wherein material of the inner package structure and the outer package structure is selected from polycarbonate (PC), polymethyl methacrylate (PMMA), polyethylene (PE), high density polyethylene (HDPE), polypropylene (PP), polystyrene (PS), polyethylene terephthalate (PET), nylon, thermosetting plastics, phenolic resin, melamine-formaldehyde resin, epoxy resin, unsaturated polyester, silicone, and combinations thereof.

9. A thermal sensor module comprising:
a substrate;
a thermal sensor disposed on the substrate;
an inner package structure disposed on the substrate and including an inner package sidewall and an inner top window, wherein the inner top window allows transmission of thermal radiation, the inner package sidewall surrounds the thermal sensor, the inner top window is located over the thermal sensor, and the inner package structure and the substrate jointly package the thermal sensor; and
an outer package structure disposed on the substrate and including an outer package sidewall and an outer top window, wherein the outer top window allows transmission of thermal radiation, the outer package sidewall surrounds the inner package sidewall, the outer top window is located over the inner top window, and the outer package structure and the substrate jointly package the thermal sensor;
wherein an orthographic projection of the inner top window projected on the substrate at least partially covers the thermal sensor, and an orthographic projection of the outer top window projected on the substrate at least partially covers the orthographic projection of the inner top window projected on this substrate.

10. The thermal sensor module as claimed in claim 9, wherein there is an inner space within the inner package structure, there is an outer space between the inner package structure and the outer package structure; wherein atmospheric pressures of the inner space and the outer space range from 200 mtorr to 50000 mtorr.

11. The thermal sensor module as claimed in claim 9, wherein a connection structure is configured between the inner package structure and the outer package structure to connect the inner packaging structure with the outer packaging structure, and the inner package structure, the outer package structure and the connection structure are integrally formed in one piece.

12. The thermal sensor module as claimed in claim 11, wherein the connection structure extends from the inner package sidewall of the inner package structure to an outer package top wall of the outer package structure and a periphery of the outer top window along a direction of the inner package sidewall for supporting the outer package top wall and the periphery of the outer top window.

13. The thermal sensor module as claimed in claim 11, wherein the connection structure extends from an inner package top wall of the inner package structure to the outer package sidewall of the outer package structure along a direction of the inner package top wall for supporting the outer package sidewall.

14. The thermal sensor module as claimed claim 9, wherein the outer top window and the inner top window are lenses with curvatures and cooperate as an imaging system to focus radiant energy on the thermal sensor.

15. The thermal sensor module as claimed claim 9, wherein material of the outer top window and the inner top window includes a plastic and an additive, and the additive is selected from the group consisting of germanium, silicon, potassium bromide, sodium chloride, zinc sulfide, zinc selenide and combinations thereof.

16. The thermal sensor module as claimed described in claim 9, wherein material of the inner package structure and the outer package structure is selected from polycarbonate (PC), polymethyl methacrylate (PMMA), polyethylene (PE), high density polyethylene (HDPE), polypropylene (PP), polystyrene (PS), polyethylene terephthalate (PET), nylon, thermosetting plastics, phenolic resin, melamine-formaldehyde resin, epoxy resin, unsaturated polyester, silicone, and combinations thereof.

17. A method for packaging a thermal sensor module, comprising:
Step S10: providing a package structure, an inner top window, an outer top window, a substrate, and a thermal sensor, wherein the substrate carries the thermal sensor;
Step S20: combining the package structure with the inner top window, wherein the package structure includes an inner package structure and an outer package structure, and fixedly mounting the inner top window into an inner opening defined by a top wall of the inner package structure;
Step S30: placing the package structure, the outer top window, and the substrate in a chamber, and placing the package structure on the substrate to completely cover the thermal sensor;
Step S40: exhausting air from the chamber, so that an inner space in the inner packaging structure and an outer space between the inner package structure and the outer package structure are all under a same atmospheric pressure;
Step S50: combining the package structure with the outer top window, and fixedly mounting the outer top window into an outer opening defined by a top wall of the outer package structure; and
Step S60: taking out the package structure from the chamber to obtain the packaged thermal sensor module.

18. The method for packaging the thermal sensor module as claimed in claim 17, wherein in Step S20 of combining the package structure with the inner top window, the inner top window is fixedly mounted onto the inner package structure by gluing and curing; and
in Step S50 of combining the package structure with the outer top window, the outer top window is fixedly mounted onto the outer package structure by gluing and curing.

19. The method for packaging the thermal sensor module as claimed in claim 17, after Step S40 of exhausting air from the chamber, further comprising a step of fixedly mounting the package structure onto the substrate by gluing and curing.

20. The method for packaging the thermal sensor module as claimed in claim 17, wherein in Step S40 of exhausting air from the chamber, the atmospheric pressure in the chamber ranges from 200 mtorr to 50000 mtorr.
